(19) United States
(12) Patent Application Publication
(10) Pub. No.: US 2002/0149077 A1
(43) Pub. Date: Oct. 17, 2002

(54) Semiconductor chip with internal ESD matching

(76) Inventor: Matthias Locher, San Jose, CA (US)

Correspondence Address: U.S. Philips Corporation, 580 White Plains Road, Tarrytown, NY, 10591, US

(21) Appl. No.: 10/056,491

(22) Filed: Jan. 17, 2002

(30) Foreign Application Priority Data
Jan. 19, 2001 (EP) 01200202.8

(51) Int. Cl. H01L 31/00

(52) U.S. Cl. 257/459

(57) ABSTRACT

Semiconductor chip comprising a high frequency (RF) circuit (2) and a chip being provided with a plurality of bonding pads (4) and an on chip electric static discharge protection (ESD) circuit (3), in which chip each circuit (2, 3) is connected with a separate bonding pad (4), an inductive connection being provided between said pads (4).

The present invention relates to a semiconductor chip comprising a high frequency (RF) circuit, and a plurality of bonding pads.

Such chips are generally known. They require electrostatic discharge protection, for which purpose commonly an ESD protective unit is provided in connection with such a chip. Such a provision is e.g. known from U.S. Pat. No. 5.869.870.

The present invention particularly thus aims at favorably protecting CMOS chips, which have shown good results per se, however which for sake of reliability are to be modeled with ESD protection when brought into mass production. A problem in such modeling exists in that the state of the art ESD protections have a much too low impedance compared to the high, mainly capacitive impedance of CMOS circuits. Also the quality factor Q of these circuits generally is not optimal when in mass production, so that proper matching of the RF CMOS circuit impedance with readily available ESD protective circuits impedance is rather difficult if not impossible.

It is an object of the current invention to provide a readily applicable, low cost solution for the above described problem without requiring circuitry external to the CMOS chip.

According to the current invention such is realized by utilizing the bonding pads of the chip such that each RF and ESD protection circuit is connected with a separate bonding pad and by providing an inductive connection between said pads. In this manner favorably a cheap and direct matching of RF and ESD protection circuits is relatively easily realized on the CMOS substrate a CMOS chip while the impedance's of the respective circuits are matched.

Preferably according to the invention such inductive connection is realized by a standardized bond wiring which, per se, is known to have a high frequency inductive characteristic and an inductance varying with the length and diameter of the wire. In the present invention such inductance realizing wiring is applied by interconnecting the RF and ESD connecting pads by a bond wiring provided to and back from a no-connect pin. In this manner unused pins of a CMOS chip are favorably utilized whilst standardized bond wires may be applied, the length of which is varied by their connection to and from a no-connect pin.

Particularly according to the invention the inductive connection between RF and ESD protection circuits is realized by a series of bond wiring by interconnecting additional chip internal pads, more in particular by bond wiring to and back from no-connect pins. In such arrangement according to the invention at least the majority of the bonds consists of wires at least generally uniform in length and thickness, thus maintaining the logistic and cost advantages of the current invention.

In a preferable embodiment the pads on the high ohmic side of the connected RF and ESD protection circuit in such arrangement are according to the invention provided shielded so as not to reduce the quality Q of the matching circuit. Favorably the working range frequency of the chip circuit ranges from 500 MHz to 3 GHz while the self-resonance of the bond wires and pins ranges above 3 GHz.

The present invention will now be further elucidated by way of a drawing in which:

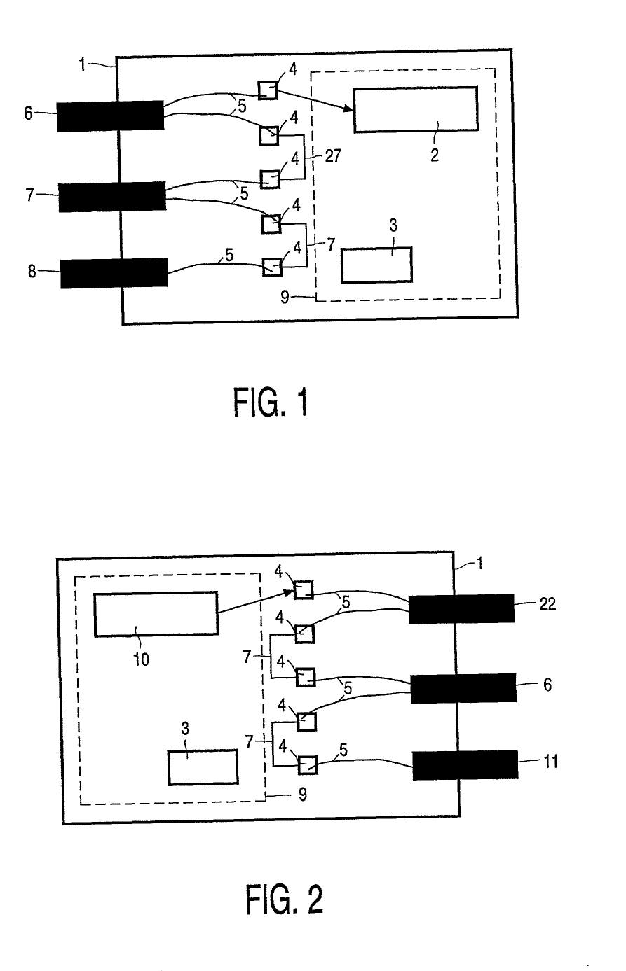

FIG. 1 is a schematic representation of a part of a CMOS chip according to the invention and suited for RF input, while

FIG. 2 is a representation in accordance with FIG. 1 of a CMOS chip suited for PA and antenna output.

In the drawing, identical references refer to identical components.

In FIG. 1, within the body one of a CMOS chip there is provided a circuitry part 9, pads 4 and pins 6 and 8, in which one bonding pad 4 is connected to an internal (Radio Frequency) RF circuit 2 and another bonding pad 4 to an ESD protection circuit 3. Pads 4 are mutually connected by standardized bond wires 5, uniform in thickness and length via open pins, alternatively denoted no-connect pins 6. In the present embodiment an internal connection layer 7 between two pads is utilized for adapting the number of bond wires 5 between the RF circuit 2 and ESD protection circuit 3, thereby determining the integral length of bond wires 5 and thereby regulating the inductance between said circuits. Pin 8 represents an RF input pin.

FIG. 2 represents a CMOS chip for power amplification purposes incorporating a power amplification or, alternatively a pre-amplification circuit 10 and an PA output or, alternatively antenna pin 12 as well as a open or no-connect VDD pin 11. In these chips several unused pins are used to improve the noise Figure of the RF CMOS circuits. Also, high RF voltage can be delivered to the power amplifier or the antenna, while high voltage ESD protection is still guaranteed. The improvement is done at almost no cost, and is in particular suited for LNA, mixer VCO and divider application.

In the chips the circuits' impedance before the ESD protection is decreased by first connecting the RF circuit to the lead frame 6 and then bonding it back to the chip pad 4. When required, as provided in the example, several additional connections to the lead frame 6 and back may be added. The bond wires 5 are modeled as an inductance. When the capacitance of RF circuit 2, 10 is converted by such inductance connection 5 or series of inductance connections 5 to a standardized impedance, e.g. near 50 or near 75 ohms, connection is made to the ESD protection circuit 3.

It was found out by the invention that the bond wires 5 favorably do not degrade performance since they are produced as very high frequency inductors. However, in a preferred embodiment the working frequency range of the internal circuits ranges from 500 to 3 GHz whilst the self-resonance of the bond wires 5 and lead frame 6 is chosen above 3 GHz. In the present set-up any ESD voltage at any pin 6, 8, 11 and 12 is connected to the ESD protection and discharged. In the Figures, the number of pins are determined by the digital back end of the CMOS chip application and some more no-connect pins for the RF part are neglectable.

In the specific application for power amplifiers, represented in FIG. 2 the output signal normally would have an expected DC value of VDD and an amplitude higher than the trigger voltage of the common ESD protection 3. This would cause the output signal to be distorted. In the current embodiment however the ESD is separated over some inductance so that the high frequency signal is blocked and does not reach the ESD. The ESD voltage from each pin is still going to the ESD protection. In an alternative embodiment the amplifier circuit may also be powered over an RF choke, which according to the invention helps to reduce the number of external components.

The current invention, apart from the preceding description and the various details of the pertaining figures, further relates to the subjects and features as defined in the following claims.

1. Semiconductor chip comprising a high frequency (RF) circuit (2) and a chip being provided with a plurality of bonding pads (4) and an on chip electric static discharge protection (ESD) circuit (3), in which chip each circuit (2, 3) is connected with a separate bonding pad (4), an inductive connection being provided between said pads (4).

2. Chip according to claim 1, characterized in that the inductive connection comprises a bond wiring (5).

3. Chip according to claim 1 or 2, characterized in that bond wiring (5) is provided to and back from a no-connect pin (6).

4. Chip according to claim 1, 2 or 3, characterized in that the inductive connection is provided in a series connection of bond wires (5).

5. Chip according to any of the preceding claims characterized in that the RF and ESD protection circuit (2, 3) are interconnected in at least one additional pin (6) to pad (4) wiring (5) in which the pads (4) are interconnected (7).

6. Chip according to any of the preceding claims characterized in that the bonds consist of wires (5) at least generally uniform in length and thickness.

7. Chip according to any of the preceding claims characterized in that the ESD connection is made after the RF circuit impedance has been converted by one of a single or series inductive bond wiring (5) to near a standardized impedance.

8. Chip according to any of the preceding claims characterized in that the pads (4) on the high ohmic side of the connected RF and ESD protection circuit are shielded.

9. Chip according to any of the preceding claims characterized, in that the chip RF circuit (2) is one of a low noise amplifier (LNA) and a mixer circuit.

10. Chip according to any of the preceding claims in which the chip RF circuit (10) is one of a power amplifier (PA) and a pre-amplifier circuit.

11. Chip according to any of the preceding claims in which the self-resonance of the bond wires (5) and pins (6) is above 3 GHz while the working range frequency of the chip circuit ranges from 500 MHz to 3 GHz.
